(19) United States
(12) Patent Application Publication
(10) Pub. No.: US 2014/0209169 A1
(43) Pub. Date: Jul. 31, 2014

(54) GLASS SUBSTRATE FOR CdTe SOLAR CELL, AND SOLAR CELL

(71) Applicant: ASAHI GLASS COMPANY, LIMITED, Tokyo (JP)

(72) Inventors: Yu HANAWA, Tokyo (JP); Yutaka KUROIWA, Tokyo (JP); Tetsuya NAKASHIMA, Tokyo (JP); Yuki KONDO, Tokyo (JP)

(73) Assignee: ASAHI GLASS COMPANY, LIMITED, Tokyo (JP)

(21) Appl. No.: 14/228,353

(22) Filed: Mar. 28, 2014

Related U.S. Application Data
(63) Continuation of application No. PCT/JP2012/073685, filed on Sep. 14, 2012.

(30) Foreign Application Priority Data
Sep. 30, 2011 (JP) 2011-216990

(51) Int. Cl. C03C 3/093; H01L 31/048; C03C 3/087

(52) U.S. Cl. CPC C03C 3/093; C03C 3/087; H01L 31/0488
USPC 136/259; 501/67; 501/70

(57) ABSTRACT

A glass substrate for a CdTe solar cell includes a base composition includes, in terms of mol % on a basis of following oxides: from 60 to 75% of SiO₂; from 1 to 7.5% of Al₂O₃; from 0 to 1% of B₂O₃; from 8.5 to 12.5% of MgO; from 1 to 6.5% of CaO; from 0 to 3% of SrO; from 0 to 3% of BaO; from 0 to 3% of ZrO₂; from 1 to 8% of Na₂O; and from 2 to 12% of K₂O, wherein MgO+CaO+SrO+BaO is from 10 to 24%, Na₂O+K₂O is from 5 to 15%, MgO/Al₂O₃ is 1.3 or more, (2Na₂O+K₂O+SrO+BaO)/(Al₂O₃+ZrO₂) is 3.3 or less, Na₂O/K₂O is from 0.2 to 2.0, Al₂O₃≧−0.94MgO+11, and CaO≧0.48MgO+6.5.

### CROSS-REFERENCE TO RELATED APPLICATIONS

The present application is a continuation application of International Application No. PCT/JP2012/073685, filed Sep. 14, 2012, which claims priority to Japanese Patent Application No. 2011-216990, filed Sep. 30, 2011. The contents of these applications are incorporated herein by reference in their entirety.

### BACKGROUND OF THE INVENTION

1. Field of the Invention

The present invention relates to a glass substrate for a CdTe solar cell and a solar cell.

2. Discussion of the Background

Group 11-13 and Group 11-16 compound semiconductors having a chalcopyrite structure and Group 12-16 compound semiconductors of a cubic system or hexagonal system have a large absorption coefficient to light in the visible to near-infrared wavelength region. Thus, they are expected as a material for high-efficiency thin film solar cell. Representative examples thereof include Cu(In,Ga)Se₂ (hereinafter referred to as “CIGS” or “Cu—In—Ga—Se”) and CdTe.

In the CdTe thin film solar cell (hereinafter may be referred to as “CdTe solar cell”), in view of the matters that it is inexpensive and that its average coefficient of thermal expansion is close to that of the back sheet glass, a soda lime glass is used as a substrate, and a solar cell is obtained.

It is known that the CdTe solar cell obtains high efficiency by conducting film formation of a CdTe layer at high temperature in forming a CdTe photoelectric conversion layer (hereinafter may be referred to as “CdTe layer”) (for example, see T. Okamoto, Jpn. J. Appl. Phys. Vol. 39 (2000), pp. 2587-2588).

Also, in order to obtain a solar cell with good efficiency, a glass material which withstands a heat treatment temperature of high temperatures has been proposed as a glass substrate for a CdTe solar cell and CIGS solar cell (for example, see WO 2011/018883).

### SUMMARY OF THE INVENTION

According to one aspect of the present invention, a glass substrate for a CdTe solar cell includes, in terms of mol % on a basis of following oxides: from 60 to 75% of SiO₂; from 1 to 7.5% of Al₂O₃; from 0 to 1% of B₂O₃; from 8.5 to 12.5% of MgO; from 1 to 6.5% of CaO; from 0 to 3% of SrO; from 0 to 3% of BaO; from 0 to 3% of ZrO₂; from 1 to 8% of Na₂O; and from 2 to 12% of K₂O. MgO+CaO+SrO+BaO is from 10 to 24%; Na₂O+K₂O is from 5 to 15%; MgO/Al₂O₃ is 1.3 or more; (2Na₂O+K₂O+SrO+BaO)/(Al₂O₃+ZrO₂) is 3.3 or less; Na₂O/K₂O is from 0.2 to 2.0; Al₂O₃≧−0.94MgO+11; and CaO≧−0.48MgO+6.5. The glass substrate has a glass transition temperature of 640° C. or higher, an average coefficient of thermal expansion within a range of from 50 to 350° C. of from 70×10⁻⁷ to 90×10⁻⁷/° C., a temperature (T₄), at which a viscosity reaches 10⁴ dPa·s, of 1,230° C. or lower, a temperature (T₂), at which a viscosity reaches 10² dPa·s, of 1,650° C. or lower, a relationship between the T₄ and a devitrification temperature (T_{L}) of T₄-T_{L}≧−30° C., and a density of 2.7 g/cm³ or less.

According to another aspect of the present invention, a solar cell includes the glass substrate, a back sheet glass facing the glass substrate, and a photoelectric conversion layer of CdTe provided between the glass substrate and the back sheet glass.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross-sectional view schematically showing an example of embodiments of a solar cell using the glass substrate for a CdTe solar cell of an embodiment of the present invention.

### DESCRIPTION OF THE EMBODIMENTS

An embodiment of the present invention provides the following glass substrate for a CdTe solar cell and the following solar cell.

(1) A glass substrate for a CdTe solar cell containing, as a base composition, in terms of mol % on the basis of the following oxides,

from 60 to 75% of SiO₂,

from 1 to 7.5% of Al₂O₃,

from 0 to 1% of B₂O₃,

from 8.5 to 12.5% of MgO,

from 1 to 6.5% of CaO,

from 0 to 3% of SrO,

from 0 to 3% of BaO,

from 0 to 3% of ZrO₂,

from 1 to 8% of Na₂O, and

from 2 to 12% of K₂O,

wherein MgO+CaO+SrO+BaO is from 10 to 24%,

Na₂O+K₂O is from 5 to 15%,

MgO/Al₂O₃ is 1.3 or more,

(2Na₂O+K₂O+SrO+BaO)/(Al₂O₃+ZrO₂) is 3.3 or less,

Na₂O/K₂O is from 0.2 to 2.0,

Al₂O₃≧−0.94MgO+11, and

CaO≧−0.48MgO+6.5,

wherein the glass substrate has a glass transition temperature of 640° C. or higher, an average coefficient of thermal expansion within a range of from 50 to 350° C. of from 70×10⁻⁷ to 90×10⁻⁷/° C., a temperature (T₄), at which a viscosity reaches 10⁴ dPa·s, of 1,230° C. or lower, a temperature (T₂), at which a viscosity reaches 10² dPa·s, of 1,650° C. or lower, a relationship between the T₄ and a devitrification temperature (T_{L}) of T₄-T_{L}≧−30° C., and a density of 2.7 g/cm³ or less.

(2) The glass substrate for a CdTe solar cell according to (1) containing, as the base composition, in terms of mol % on the basis of the following oxides,

from 62 to 73% of SiO₂,

from 1.5 to 7% of Al₂O₃,

from 0 to 1% of B₂O₃,

from 9 to 12.5% of MgO,

from 1.5 to 6.5% of CaO,

from 0 to 2.5% of SrO,

from 0 to 2% of BaO,

from 0.5 to 3% of ZrO₂,

from 1 to 7.5% of Na₂O, and

from 2 to 10% of K₂O,

wherein MgO+CaO+SrO+BaO is from 11 to 22%,

Na₂O+K₂O is from 6 to 13%,

MgO/Al₂O₃ is 1.4 or more,

(2Na₂O+K₂O+SrO+BaO)/(Al₂O₃+ZrO₂) is from 0.5 to 3,

Na₂O/K₂O is from 0.4 to 1.5,

Al₂O₃≧−0.94MgO+12, and

CaO≧−0.48MgO+7,

wherein the glass substrate has the glass transition temperature of 645° C. or higher, the average coefficient of thermal expansion within a range of from 50 to 350° C. of from 70×10⁻⁷ to 85×10⁻⁷/° C., the temperature (T₄), at which a viscosity reaches 10⁴ dPa·s, of 1,220° C. or lower, the temperature (T₂), at which a viscosity reaches 10² dPa·s, of 1,630° C. or lower, the relationship between the T₄ and the devitrification temperature (T_{L}) of T₄-T_{L}≧−20° C., and the density of 2.6 g/cm³ or less.

(3) The glass substrate for a CdTe solar cell according to (1) or (2), wherein an iron oxide is contained in an amount of 0.06 parts by mass or less, measured as Fe₂O₃ amount, based on 100 parts by mass of the base composition.

(4) The glass substrate for a CdTe solar cell according to any one of (1) to (3),

wherein MgO, CaO, SrO and BaO in the base composition satisfies that MgO/(MgO+CaO+SrO+BaO) is 0.4 or more in terms of mol % on the basis of the oxides.

(5) A solar cell, comprising a glass substrate, a back sheet glass, and a photoelectric conversion layer of CdTe formed between the glass substrate and the back sheet glass,

wherein, of the glass substrate and the back sheet glass, at least the glass substrate is the glass substrate for a CdTe solar cell as described in any one of (1) to (4).

The glass substrate for a CdTe solar cell of the embodiment of the present invention can have properties of high transmittance, high glass transition temperature, a predetermined average coefficient of thermal expansion, high glass strength, low glass density, and meltability, formability and prevention of devitrification upon sheet glass forming with good balance, and a solar cell exhibiting high cell efficiency can be provided by using the glass substrate for a CdTe solar cell of the embodiment of the present invention.

Specifically, according to the embodiment of the present invention, the following technical advantages are obtained with good balance: a glass substrate having high heat resistance can be obtained because of high glass transition temperature of the glass; a CdTe solar cell having high cell efficiency can be obtained because of high transmittance of the glass substrate; during the process of manufacturing a CdTe solar cell, peeling of the CdTe layer on the glass substrate during and after deposition and deformation with respect to temperature change during and after a step of adhering to a back sheet glass can be prevented because the glass substrate has an appropriate average coefficient of thermal expansion; a CdTe solar cell which has an advantage in fabrication and use can be obtained because the glass substrate has an improved strength and a reduced weight; and a glass having a good meltability and formability can be obtained.

The embodiment will now be described in detail.

### <Glass Substrate for CdTe Solar Cell of the Embodiment of the Present Invention>

The glass substrate for a CdTe solar cell of the embodiment of the present invention will be explained below.

The glass substrate for a CdTe solar cell of the embodiment of the present invention relates to a glass substrate for a CdTe solar cell containing, as a base composition, in terms of mol % on the basis of the following oxides,

from 60 to 75% of SiO₂,

from 1 to 7.5% of Al₂O₃,

from 0 to 1% of B₂O₃,

from 8.5 to 12.5% of MgO,

from 1 to 6.5% of CaO,

from 0 to 3% of SrO,

from 0 to 3% of BaO,

from 0 to 3% of ZrO₂,

from 1 to 8% of Na₂O, and

from 2 to 12% of K₂O,

wherein MgO+CaO+SrO+BaO is from 10 to 24%,

Na₂O+K₂O is from 5 to 15%,

MgO/Al₂O₃ is 1.3 or more,

(2Na₂O+K₂O+SrO+BaO)/(Al₂O₃+ZrO₂) is 3.3 or less,

Na₂O/K₂O is from 0.2 to 2.0,

Al₂O₃≧−0.94MgO+11, and

CaO≧−0.48MgO+6:5,

wherein the glass substrate has a glass transition temperature of 640° C. or higher, an average coefficient of thermal expansion within a range of from 50 to 350° C. of from 70×10⁻⁷ to 90×10⁻⁷/° C., a temperature (T₄), at which a viscosity reaches 10⁴ dPa·s, of 1,230° C. or lower, a temperature (T₂), at which a viscosity reaches 10² dPa·s, of 1,650° C. or lower, a relationship between the T₄ and a devitrification temperature (T_{L}) of T₄-T_{L}≧−30° C., and a density of 2.7 g/cm³ or less.

As used herein, the term “base composition” is a composition which includes SiO₂, Al₂O₃, B₂O₃, MgO, CaO, SrO, BaO, ZrO₂, Na₂O, K₂O and TiO₂ as main raw materials of the glass substrate. The raw materials for a glass substrate may contain raw materials components other than those.

As used herein, the term “composition for a glass substrate” refers to both of the base composition and raw material components other than the base composition. In the case where TiO₂ is not intentionally added, TiO₂ is not included in the base composition.

The glass transition temperature (Tg) of the glass substrate for a CdTe solar cell of the embodiment of the present invention is 640° C. or higher, and is higher than the glass transition temperature of soda lime glass. For the purpose of ensuring the formation of a CdTe layer at high temperatures, the glass transition temperature (Tg) is preferably 645° C. or higher, more preferably 650° C. or higher and still more preferably 655° C. or higher. For the purpose of not excessively increasing the viscosity during melting, the glass transition temperature is preferably 750° C. or lower, more preferably 720° C. or lower, and still more preferably 690° C. or lower.

The average coefficient of thermal expansion within the range of from 50 to 350° C. of the glass substrate for a CdTe solar cell of the embodiment of the present invention is from 70×10⁻⁷ to 90×10⁻⁷/° C. In the case of using a soda lime glass sheet or a glass sheet having an average coefficient of thermal expansion of from 80 to 90×10⁻⁷/° C. as the back sheet glass, if the average coefficient of thermal expansion within the range of from 50 to 350° C. of the glass substrate is less than 70×10⁻⁷/° C., a difference in expansion between the glass substrate and the back sheet glass is excessively large, and there is a concern that a module warps due to the temperature change during the step of adhering the glass substrate with the back sheet glass when forming the module or after setting up a solar cell. On the other hand, if the average coefficient of thermal expansion exceeds 90×10⁻⁷/° C., a difference in thermal expansion between the glass substrate and the CdTe layer is excessively large, and defect such as peeling is prone to occur. The average coefficient of thermal expansion is preferably 85×10⁻⁷/° C. or less.

In the glass substrate for a CdTe solar cell of the embodiment of the present invention, a relationship between a temperature (T₄), at which a viscosity reaches 10⁴ dPa·s, and a devitrification temperature (T_{L}) is T₄-T_{L}≧30° C. When T₄-T_{L} is lower than −30° C., devitrification is prone to occur during the formation of the sheet glass, and thus, there is a concern that forming of a glass sheet becomes difficult. The relationship of T₄-T_{L} is preferably −20° C. or higher, more preferably −10° C. or higher, still more preferably 0° C. or higher, and especially preferably 10° C. or higher.

Here, the devitrification temperature means a maximum temperature at which a crystal is not precipitated on the glass surface and inside the glass when the glass is kept in a specific temperature for 17 hours.

Taking the formability of the glass sheet, that is, improvement in flatness and improvement in productivity, into consideration, T₄ is 1,230° C. or lower, preferably 1,220° C. or lower, and more preferably 1,210° C. or lower.

In the glass substrate for a CdTe solar cell of the embodiment of the present invention, taking meltability of a glass, that is, improvement in homogeneity and improvement in productivity, into consideration, a temperature (T₂), at which a viscosity reaches 10² dPa·s, is 1,650° C. or lower. T₂ is preferably 1,630° C. or lower, and more preferably 1,620° C. or lower.

In the glass substrate for a CdTe solar cell of the embodiment of the present invention, Young's modulus is preferably 75 GPa or more. If the Young's modulus is smaller than 75 GPa, there is a concern that strain amount under constant stress is increased, and warpage occurs in a production step, thereby causing disadvantages, and film formation cannot be normally performed. Furthermore, warpage in a product becomes large, and thus the case is not preferred. The Young's modulus is preferably 76 GPa or more, and more preferably 77 GPa or more. In the case of producing a glass substrate by an ordinary method such as a float process or a fusion process, given that the glass composition range should be controlled so that the manufacturing can be easily conducted, the Young's modulus is generally 90 GPa or less.

Specific elastic modulus (E/d) obtained by dividing Young's modulus (hereinafter referred to as “E”) by a density (hereinafter referred to as “d”) is preferably 28 GPa·cm³/g or more. If the specific elastic modulus is smaller than 28 GPa·cm³/g, there is a concern that the glass substrate warps by own weight during conveying by rollers or in the case of being partially supported, and the glass substrate is not normally flowed in a production step. The specific elastic modulus is more preferably 29 GPa·cm³/g or more, and still more preferably 30 GPa·cm³/g or more. In the case of producing a glass substrate by an ordinary method such as a float process or a fusion process, given that the glass composition range should be controlled so that the manufacturing can be easily conducted, the specific elastic modulus is generally 37.5 GPa·cm³/g or less. To achieve the specific elastic modulus (E/d) of 28 GPa·cm³/g or more, the Young's modulus and density should fall within the ranges specified in the present application.

The glass substrate for a CdTe solar cell of the embodiment of the present invention preferably has a density of 2.7 g/cm³ or less. If the density exceeds 2.7 g/cm³, product weight increases and thus the case is not preferred. The density is more preferably 2.65 g/cm³ or less, and sill more preferably 2.6 g/cm³ or less. In the case of producing a glass substrate by an ordinary method such as a float process or a fusion process, given that the glass composition range should be controlled so that the manufacturing can be easily conducted, the density is generally 2.4 g/cm³ or more.

In the case of using the glass substrate of the embodiment of the present invention in a glass substrate for a CdTe solar cell, taking cell efficiency into consideration, the average transmittance (hereinafter may be referred to as “Tave”) of a glass substrate in a wavelength of from 500 to 800 nm is preferably 90.3% or more, more preferably 90.4% or more, and still more preferably 90.5% or more, as converted into 2 mm thickness.

In the glass substrate for a CdTe solar cell of the embodiment of the present invention, a brittleness index is preferably less than 7,000 m^{-1/2}. If the brittleness index is 7,000 m^{-1/2} or more, the glass substrate is prone to be broken in the manufacturing process of the solar cell and thus the case is not preferred. The brittleness index is more preferably 6,900 m^{-1/2} or less and still more preferably 6,800 m^{-1/2} or less. In the case of producing the glass substrate by an ordinary process such as a float process or fusion process, given that the glass composition range should be controlled so that the manufacturing can be easily conducted, the brittleness index is generally 5,000 m^{-1/2} or more.

In the embodiment of the present invention, the brittleness index of the glass substrate is obtained as “B” defined by the following formula (1) (J. Sehgal, et al., J. Mat. Sci. Lett., 14, 167 (1995)).

c/a=0.0056B^{2/3}P^{1/6} (1)

Here, P is a pressing load of a Vickers indenter and a and c are a diagonal length of the Vickers indentation mark and a length of cracks formed from the four corners (total length of symmetrical two cracks including the mark of the indenter). The brittleness index B is calculated using the size of the Vickers indentation marks formed on various glass substrate surface and the formula (1).

The composition for the glass substrate in the glass substrate for a CdTe solar cell of the embodiment of the present invention is described below. The reasons why the contents of the base composition and the other components are limited are as follows.

SiO₂: SiO₂ is a component capable of forming a network of glass, and if its content is less than 60 mol % (hereinafter referred to simply as “%”), there is a concern that the heat resistance and chemical durability of the glass substrate are lowered, and the average coefficient of thermal expansion within the rage of 50 to 350° C. increases. The content thereof is preferably 62% or more, more preferably 63% or more, and still more preferably 64% or more.

However, if it exceeds 75%, there is a concern that the viscosity of the glass at a high temperature increases, and a problem of the deterioration of the meltability is caused. The content thereof is preferably 73% or less, more preferably 70% or less, and still more preferably 69% or less.

Al₂O₃: Al₂O₃ increases the glass transition temperature, enhances the weather resistance (solarization), heat resistance and chemical durability, and increases the Young's modulus. If its content is less than 1%, there is a concern that the glass transition temperature is lowered. Also, there is a concern that the average coefficient of thermal expansion within the range of 50 to 350° C. increases. The content thereof is preferably 1.5% or more, and more preferably 2% or more.

However, if it exceeds 7.5%, there is a concern that the viscosity of the glass at a high temperature increases, and the meltability is deteriorated. Also, there is a concern that the devitrification temperature increases, and the formability is deteriorated. The content thereof is preferably 7% or less.

B₂O₃: B₂O₃ may be contained in an amount of up to 1% for the purposes of enhancing the meltability, etc. If its content exceeds 1%, the glass transition temperature decreases, and thus is not preferable for a process for forming the CdTe layer. In addition, the devitrification temperature is increased to thereby easily cause the devitrification, resulting in difficulty of forming the glass sheet. In addition, there is a concern that, during forming the CdTe layer as the photoelectric conversion layer, boron ions diffuse into the layer, and thus, the cell efficiency is lowered. In addition, there is a concern that the volatilization amount of B₂O₃ is increased during melting of glass, and thus, the load of facilities is increased. The content thereof is preferably 0.5% or less. It is more preferred that B₂O₃ is not substantially contained.

The expression “is not substantially contained” means that it is not contained except the case where it is contained as unavoidable impurities originated from raw materials or the like, that is, means that it is not intentionally incorporated.

MgO: MgO is contained because it has effects for decreasing the viscosity during melting of glass, and promoting melting. However, if its content is less than 8.5%, there is a concern that the viscosity of the glass at a high temperature increases, and the meltability is deteriorated. The content thereof is preferably 9% or more, more preferably 9.5% or more, and still more preferably 10% or more.

However, if it exceeds 12.5%, there is a concern that the average coefficient of thermal expansion within the range of 50 to 350° C. increases. Also, there is a concern that the devitrification temperature increases. The content thereof is preferably 12% or less.

CaO: CaO can be contained because it has effects for decreasing the viscosity during melting of glass, and promoting melting. The content thereof is preferably 1% or more, more preferably 1.5% or more, and still more preferably 2% or more. However, if its content exceeds 6.5%, there is a concern that the average coefficient of thermal expansion within the range of 50 to 350° C. of the glass substrate increases. The content thereof is preferably 6% or less.

SrO: SrO can be contained because it has effects for decreasing the viscosity during melting of glass, and promoting melting. The content thereof is preferably 0.5% or more. However, if its content exceeds 3%, there is a concern that the average coefficient of thermal expansion within the range of 50 to 350° C. of the glass substrate increases, the density of the glass substrate increases, and the later-described brittleness index of the glass substrate increases. The content thereof is preferably 2.5% or less, and more preferably 2% or less.

BaO: BaO can be contained because it has effects for decreasing the viscosity during melting of glass, and promoting melting. However, if its content exceeds 3%, there is a concern that the cell efficiency is lowered, and the average coefficient of thermal expansion within the range of 50 to 350° C. of the glass substrate increases, the density of the glass substrate increases, and the brittleness index of the glass substrate increases. In addition, there is a concern that the Young's modulus is lowered. The content thereof is preferably 2% or less, more preferably 1.5% or less, and still more preferably 1.0% or less. It is especially preferred that BaO is not substantially contained.

The expression “is not substantially contained” means that it is not contained except the case where it is contained as unavoidable impurities originated from raw materials or the like, that is, means that it is not intentionally incorporated.

ZrO₂: ZrO₂ can be contained because it has effects for decreasing the viscosity during melting of glass, and promoting melting. However, if its content exceeds 3%, there is a concern that the cell efficiency is lowered, or devitrification temperature is increased to thereby easily cause the devitrification, resulting in difficulty of forming the sheet glass. The content thereof is preferably 2.5% or less. The content thereof is preferably 0.5% or more, and more preferably 1% or more.

MgO, CaO, SrO, and BaO: MgO, CaO, SrO, and BaO are contained in an amount of 10% or more in total from the standpoints of decreasing the viscosity during melting of glass, and promoting melting. However, if the total content exceeds 24%, there is a concern that the devitrification temperature increases and the formability is deteriorated. The total content is preferably 11% or more, more preferably 12% or more, and still more preferably 13% or more. Also, the total content is preferably 22% or less, more preferably 20% or less, and still more preferably 19% or less.

Regarding MgO, CaO, SrO and BaO, the value of the following formula (2) is 0.4 or more in order to decrease light absorption derived from the inclusion of Fe₂O₃.

MgO/(MgO+CaO+SrO+BaO) (2)

The present inventors have found that, if the amount of Mg is larger than amounts of other alkaline earth metal elements, the light absorption derived from Fe₂O₃ is suppressed low. This is considered to be due to that environment around Fe ions in a glass is changed depending on the proportion of Mg. For this reason, in the embodiment of the present invention, in addition to the range of MgO, the above formula (2) specifying the proportion of MgO in alkaline earth metal oxides is preferably 0.4 or more, more preferably 0.5 or more, still more preferably 0.55 or more, and especially preferably 0.6 or more. In the glass of the embodiment of the present invention, for the purpose of preventing excessive increase in density, SrO and BaO are contained in an amount of 3% or less. Low density suitable for use in a CdTe solar cell is achieved by increasing the proportion of MgO which is the lightest component among MgO, CaO, SrO and BaO.

Na₂O: Na₂O has effects for decreasing the viscosity at a melting temperature of a glass and making it easy to perform melting, and therefore, it is contained in an amount of from 1 to 8%. If the content is less than 1%, the average coefficient of thermal expansion within the range of 50 to 350° C. is excessively small, and thus the case is not preferred. The content thereof is preferably 1.5% or more, and more preferably 2% or more.

If the content of Na₂O exceeds 8%, the average coefficient of thermal expansion within the range of 50 to 350° C. tends to become large, and the glass transition temperature tends to be lowered. In addition, the chemical durability is deteriorated. In addition, there is a concern that Young's modulus is lowered. Furthermore, there is a concern that the diffusion of Na into a CdTe layer is excessively large, and the cell efficiency is lowered. The content thereof is preferably 7.5% or less, and more preferably 7% or less.

K₂O: K₂O has the same effects as those in Na₂O, and therefore, it is contained in an amount of from 2 to 12%. However, if its content exceeds 12%, there is a concern that the diffusion of K into a CdTe layer is excessively large, and the cell efficiency is lowered. In addition, there is a concern that the glass transition temperature is lowered, and the average coefficient of thermal expansion within the range of 50 to 350° C. becomes large. Furthermore, there is a concern that Young's modulus is lowered. In the case where K₂O is contained, its content is preferably 2% or more, more preferably 3% or more, and still more preferably 3.5% or more. The content thereof is preferably 10% or less, more preferably 9% or less, and still more preferably 8.5% or less.

Na₂O and K₂O: For the purpose of sufficiently decreasing the viscosity at a melting temperature of glass and for the purpose of adjusting the average coefficient of thermal expansion within the range of 50 to 350° C. to a proper value, the total content of Na₂O and K₂O is from 5 to 15%. The total content thereof is preferably 6% or more, and more preferably 7% or more. However, if the total content thereof exceeds 15%, there is a concern that the glass transition temperature is excessively lowered. The total content thereof is preferably 13% or less, and more preferably 12.5% or less.

The ratio of Na₂O to K₂O, i.e. Na₂O/K₂O, is 0.2 or more. If the amount of Na₂O is small as compared with the amount of K₂O, there is a concern that the viscosity during melting is excessively high, and the production of a glass becomes difficult. The ratio is preferably 0.4 or more, more preferably 0.5 or more, and still more preferably 0.6 or more. However, if the ratio exceeds 2.0, there is a concern that the glass transition temperature excessively decreases. The ratio is preferably 1.5 or less, more preferably 1.4 or less, and still more preferably 1.3 or less.

Al₂O₃ and MgO: For the purpose of suppressing the increase of the devitrification temperature, a ratio MgO/Al₂O₃ is 1.3 or more. If the ratio is less than 1.3, there is a concern that the devitrification temperature increases. The ratio is preferably 1.4 or more, and more preferably 1.5 or more. Taking weatherability and chemical durability into consideration, the ratio is preferably 5 or less, more preferably 4 or less, and still more preferably 3 or less.

In addition, the following relationship is satisfied: Al₂O₃≧−0.94MgO+11. In this case, the present inventors have found that Tg can easily be controlled to 640° C. or higher in the embodiment of the present invention. This is considered due to that Al₂O₃ and MgO have large effect for increasing Tg as compared with other elements. The coefficient 0.94 means that the effect for increasing Tg of MgO is slightly inferior to that of Al₂O₃. The relationship is preferably Al₂O₃≧−0.94MgO+12, more preferably Al₂O₃≧−0.94MgO+13, still more preferably Al₂O₃≧−0.94MgO+13.5, and especially preferably Al₂O₃≧−0.94MgO+14.

CaO and MgO: The following relationship is satisfied: CaO≧−0.48MgO+6.5. In this case, the present inventors have found that T₄ can easily be controlled to 1,230° C. or lower in the embodiment of the present invention. This is considered due to that CaO and MgO have large effect for decreasing T₄ while maintaining Tg as compared with other elements. The coefficient 0.48 means that the contribution of MgO is about ½ of CaO. The relationship is preferably CaO≧−0.48MgO+7, more preferably CaO≧−0.48MgO+7.5, and still more preferably CaO≧−0.48MgO+8.

Na₂O, K₂O, SrO, BaO, Al₂O₃ and ZrO₂: For the purpose of maintaining the glass transition temperature sufficiently high and further for the purpose of improving weather resistance, a value of the following formula (3) is 3.3 or less.

(2Na₂O+K₂O+SrO+BaO)/(Al₂O₃+ZrO₂) (3)

From the results of experiments and trial and error, the present inventors have found that in the case where each of the above components satisfies the range of the present application and the value obtained from the above formula (3) is 3.3 or less, the glass transition temperature can be maintained sufficiently high.

If the value exceeds 3.3, there is a concern that the glass transition temperature decreases or the weather resistance is deteriorated. Moreover, if the value becomes excessively low, there is a tendency that the viscosity at high temperatures increases, resulting in deterioration of the meltability and formability, and thus, the value is preferably 0.5 or more, and more preferably 1 or more.

The reason why a coefficient of 2 is multiplied by the content of Na₂O is that Na₂O shows the effect of decreasing Tg higher than the case where other components show.

TiO₂: The glass substrate of the embodiment of the present invention has high content of alkaline earth metal oxides, especially MgO, as compared with ordinary soda lime glass. Therefore, a foam layer is prone to be formed on the surface of a molten glass. If the foam layer is formed, there is a tendency that the temperature of the molten glass does not increase, resulting in difficulty of clarification, and productivity is deteriorated. For the purpose of thinning the foam layer formed on the surface of the molten glass or causing the foam layer to disappear, a titanium compound is supplied as a defoamer to the foam layer formed on the surface of the molten glass in some cases. The titanium compound is incorporated into a molten glass and is present as TiO₂. The titanium compound may be an inorganic titanium compound (such as titanium tetrachloride or titanium oxide) and may be an organic titanium compound. Examples of the organic titanium compound include a titanic acid ester or its derivative, titanium chelate or its derivative, titanium acylate or its derivative, and oxalic titanate. TiO₂ is sometimes contained as impurities in a glass. Alternatively, TiO₂ may be added for the purpose of, for example, improving meltability. If its content is large, there is a tendency that transmittance at a wavelength of from 350 to 550 nm is lowered. TiO₂ has small influence on an average transmittance in a range of from 500 to 800 nm that contributes to conversion efficiency of a CdTe solar cell, and therefore can be contained in an amount up to 3%. The content thereof is preferably 2.5% or less, more preferably 2% or less, and still more preferably 1.5% or less.

In the case where TiO₂ is not intentionally contained, TiO₂ contained in a glass as impurities from the defoamer, industrial materials and the like is preferably contained in an amount of from 0.0001 to 0.2 parts by mass, more preferably from 0.001 to 0.15 parts by mass, and still more preferably 0.001 to 0.1 parts by mass, based on 100 parts by mass of the base composition (SiO₂, Al₂O₃, B₂O₃, MgO, CaO, SrO, BaO, ZrO₂, Na₂O and K₂O) of the glass substrate.

Iron oxide: In the glass substrate of the embodiment of the present invention, for the purpose of securing transmittance and increasing cell efficiency, an iron oxide is preferably contained in an amount of 0.06 parts by mass or less, more preferably 0.055 parts by mass or less, still more preferably 0.05 parts by mass or less, and especially preferably 0.045 parts by mass or less, as converted into Fe₂O₃ amount, based on 100 parts by mass of the base composition (SiO₂, Al₂O₃, B₂O₃, MgO, CaO, SrO, BaO, ZrO₂, Na₂O and K₂O).

If the content of the iron oxide is 0.01 parts by mass or more, since industrial materials in which contamination of iron oxide components is unavoidable can be used, industrial production becomes easy, and thus this case is preferred. Moreover, if the content of the iron oxide is 0.01 parts by mass or more, absorption of radiation becomes remarkably large during melting, and thus, the temperature of a glass is easy to increase, and this results in no problem in the production. The content thereof is preferably 0.015 parts by mass or more, and more preferably 0.02 parts by mass or more.

In the embodiment of the present invention, as the iron oxide, red iron oxide, iron oxide powder and the like can be exemplified.

SnO₂: For the purpose of securing transmittance of the glass substrate, the content of SnO₂ is preferably 0.30 parts by mass or less, more preferably 0.25 parts by mass or less, and still more preferably 0.20 parts by mass or less, based on 100 parts by mass of the base composition (SiO₂, Al₂O₃, B₂O₃, MgO, CaO, SrO, BaO, ZrO₂, Na₂O and K₂O).

The glass substrate for a CdTe solar cell of the embodiment of the present invention preferably relates to the glass substrate for a CdTe solar cell, containing, as the base composition, in terms of mol % on the basis of the following oxides,

from 62 to 73% of SiO₂,

from 1.5 to 7% of Al₂O₃,

from 0 to 1% of B₂O₃,

from 9 to 12.5% of MgO,

from 1.5 to 6.5% of CaO,

from 0 to 2.5% of SrO,

from 0 to 2% of BaO,

from 0.5 to 3% of ZrO₂,

from 1 to 7.5% of Na₂O, and

from 2 to 10% of K₂O,

wherein MgO+CaO+SrO+BaO is from 11 to 22%,

Na₂O+K₂O is from 6 to 13%,

MgO/Al₂O₃ is 1.4 or more,

(2Na₂O+K₂O+SrO+BaO)/(Al₂O₃+ZrO₂) is from 0.5 to 3,

Na₂O/K₂O is from 0.4 to 1.5,

Al₂O₃≦−0.94MgO+12, and

CaO≧−0.48MgO+7,

wherein the glass substrate has the glass transition temperature of 645° C. or higher, the average coefficient of thermal expansion within a range of from 50 to 350° C. of from 70×10⁻⁷ to 85×10⁻⁷/° C., the temperature (T₄), at which a viscosity reaches 10⁴ dPa·s, of 1,220° C. or lower, the temperature (T₂), at which a viscosity reaches 10² dPa·s, of 1,630° C. or lower, the relationship between the T₄ and the devitrification temperature (T_{L}) of T₄-T_{L}-20° C., and the density of 2.6 g/cm³ or less.

It is preferred that the glass substrate for a CdTe solar cell of the embodiment of the present invention contains components of SiO₂, Al₂O₃, B₂O₃, MgO, CaO, SrO, BaO, ZrO₂, Na₂O and K₂O as the base composition in the above-described contents, and contains an iron oxide in an amount of 0.06 parts by mass or less, as converted into Fe₂O₃ amount, based on 100 parts by mass of the base composition, as impurity or addition component. According to this, transmittance increases, and a CdTe solar cell using the glass substrate of the embodiment of the present invention has high cell efficiency.

Though the glass substrate for a CdTe solar cell of the embodiment of the present invention is essentially composed of the foregoing base composition, it may contain other components each in an amount of 1 part by mass or less and in an amount of 5 parts by mass or less in total, based on 100 parts by mass of the base composition, within the range where an object of the present invention is not impaired. For example, there may be the case where ZnO, Li₂O, WO₃, Nb₂O₅, V₂O₅, Bi₂O₃, MoO₃, TiO₂, P₂O₅, and the like may be contained for the purpose of improving the weather resistance, melting properties, devitrification, ultraviolet ray shielding, refractive index, and the like.

Also, for the purpose of improving the melting properties and fining property of glass, SO₃, F and Cl may be added into the base composition such that these materials are contained each in an amount of 1 part by mass or less and in an amount of 2 parts by mass or less in total, based on 100 parts by mass of the base composition, in the glass.

Also, for the purpose of enhancing the chemical durability of glass substrate, Y₂O₃ and La₂O₃ may be contained in an amount of 2 parts by mass or less in total based on 100 parts by mass of the base composition in the glass.

Also, for the purpose of adjusting the color tone of the glass substrate, colorants such as CeO₂ may be contained in the glass. The content of such colorants is preferably 0.2 parts by mass or less in total based on 100 parts by mass of the base composition.

Taking an environmental load into consideration, it is preferable that the glass substrate for a CdTe solar cell of the embodiment of the present invention does not substantially contain As₂O₃ and Sb₂O₃. Also, taking the stable achievement of float forming into consideration, it is preferable that the glass substrate does not substantially contain ZnO. However, the glass substrate for a CdTe solar cell of the embodiment of the present invention may be produced by a fusion process without limitation to forming by the float process.

As described above, the expression “is not substantially contained” means that it is not contained except the case where it is contained as unavoidable impurities originated from raw materials or the like, that is, means that it is not intentionally incorporated.

### <Manufacturing Method of Glass Substrate for CdTe Solar Cell of the Embodiment of the Present Invention>

A manufacturing method of the glass substrate for a CdTe solar cell of the embodiment of the present invention will be described.

In the case of manufacturing the glass substrate for a CdTe solar cell of the embodiment of the present invention, similar to the case of manufacturing conventional glass substrates for a solar cell, a melting/fining step and a forming step are carried out. Since the glass substrate for a CdTe solar cell of the embodiment of the present invention is an alkali glass substrate containing an alkali metal oxide (Na₂O and K₂O), SO₃ can be effectively used as a refining agent, and a float process or a fusion process (down draw process) is suitable as the forming method.

In the manufacturing step of the glass substrate for a solar cell, it is preferable to adopt, as a method for forming a glass into a sheet form, a float process by which a glass substrate with a large area can be formed easily and stably with an increase in size of solar cells.

A preferred embodiment of the manufacturing method of the glass substrate for a CdTe solar cell of the embodiment of the present invention will be described. First of all, a molten glass obtained by melting raw materials is formed into a sheet form. For example, the raw materials are prepared so that the glass substrate to be obtained has a composition as mentioned above, and the raw materials are continuously thrown into a melting furnace, followed by heating at from 1,550 to 1,700° C. to obtain a molten glass. Then, this molten glass is formed into a glass sheet in a ribbon form by applying, for example, a float process.

Subsequently, the glass sheet in the ribbon form is taken out from the float forming furnace, followed by cooling to a room temperature state by cooling means, and cutting to obtain a glass substrate for a CdTe solar cell.

### <Use Applications of Glass Substrate for CdTe Solar Cell>

The glass substrate for a CdTe solar cell of the embodiment of the present invention is suitable as a glass substrate or back sheet glass for a CdTe solar cell.

In the case of applying the glass substrate for a CdTe solar cell of the embodiment of the present invention to the glass substrate, the thickness of the glass substrate is preferably 3 mm or less, more preferably 2 mm or less, and still more preferably 1.5 mm or less. Also, a method for forming a CdTe layer on the glass substrate is not particularly limited. Heating temperature during the formation of the CdTe layer can be set to from 500 to 700° C., preferably from 550 to 700° C., more preferably from 600 to 700° C., and still more preferably from 640 to 700° C.

In the case of using the glass substrate for a CdTe solar cell of the embodiment of the present invention for only the glass substrate, a back sheet glass or the like are not particularly limited, but those having an average coefficient of thermal expansion near that of the glass substrate of the embodiment of the present invention are preferred. Other examples of the composition of the back sheet glass include soda lime glass and the like.

In the case of using the glass substrate for a CdTe solar cell of the embodiment of the present invention as a back sheet glass, the thickness of the back sheet glass is preferably 3 mm or less, more preferably 2 mm or less, and still more preferably 1.5 mm or less. Also, a method for assembling the back sheet glass and the glass substrate including a CdTe layer is not particularly limited. In the case of assembling upon heating, its heating temperature can be set to from 500 to 700° C., and preferably from 600 to 700° C.

If the glass substrate for a CdTe solar cell of the embodiment of the present invention is used for both a glass substrate and a back sheet glass for a CdTe solar cell, since the average coefficient of thermal expansion within the range of from 50 to 350° C. of those is equal, thermal decomposition or the like does not occur during assembling the solar cell, and furthermore warpage caused by temperature change after setting up a solar cell can be reduced. Thus, the case is preferred.

### <CdTe Solar Cell in the Embodiment of the Present Invention>

Next, the solar cell in the embodiment of the present invention will be described.

The solar cell in the embodiment of the present invention includes a glass substrate, a back sheet glass, and a photoelectric conversion layer of CdTe (CdTe layer) arranged between the glass substrate and the back sheet glass, and of the glass substrate and the back sheet glass, at least the glass substrate is the glass substrate for a CdTe solar cell of the embodiment of the present invention.

Alternatively, a solar cell in which, in the constitution of the above-described solar cell, a back film having oxygen permeation resistance is used in place of the back sheet glass may be used.

The solar cell in the embodiment of the present invention will be hereunder described in detail by reference to the accompanying drawing. It should not be construed that the present invention is limited to the accompanying drawing.

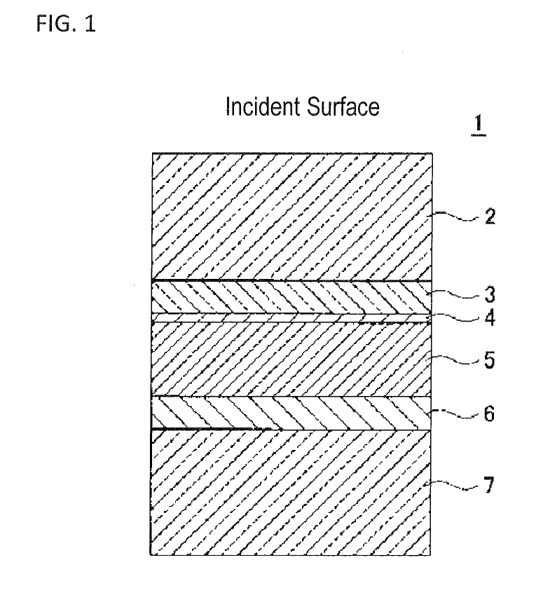

FIG. 1 is a cross-sectional view schematically showing an example of the embodiments of the CdTe solar cell in the embodiment of the present invention.

In FIG. 1, the solar cell (CdTe solar cell) 1 in the embodiment of the present invention includes a glass substrate 2 having a thickness of from 1 to 3 mm, a back sheet glass 7 having a thickness of from 1 to 3 mm, and a CdTe layer 5 having a thickness of from 3 to 15 μm between the glass substrate 2 and the back sheet glass 7. The glass substrate 2 is preferably composed of the glass substrate for a CdTe solar cell of the embodiment of the present invention as described above.

The solar cell 1 includes a transparent conductive film 3 having a thickness of from 100 to 1,000 nm on the glass substrate 2. Examples of the transparent conductive film 3 include Sn-doped In₂O₃ and F-doped In₂O₃. The solar cell 1 includes a buffer layer 4 (for example, CdS layer) having a thickness of from 50 to 300 nm on the transparent conductive layer 3, and the CdTe layer 5 on the buffer layer 4. Also, the solar cell 1 includes a back electrode 6 (for example, Cu-doped carbon electrode or Mo electrode) having a thickness of 100 to 1,000 nm on the CdTe layer 5, and the back sheet glass 7 on the back electrode 6. A gap between the back electrode 6 and the back sheet glass 7 is preferably sealed with a resin or adhered with a resin for adhesion. The glass substrate for a CdTe solar cell of the embodiment of the present invention may be used for the back sheet glass 7.

In the embodiment of the present invention, end parts of the CdTe layer or end parts of the solar cell may be sealed. Examples of a material for sealing include materials having the same composition as those in the glass substrate for a CdTe solar cell of the embodiment of the present invention, the other glasses and resins.

It should not be construed that the thickness of each layer of the solar cell shown in the accompanying drawing is not limited to that shown in the drawing.

### EXAMPLES

The present invention will be hereunder described in more detail with reference to Examples and Manufacturing Examples, but it should not be construed that the present invention is limited to these Examples and Manufacturing Examples.

Examples of the glass substrate for a CdTe solar cell of the present invention (Nos. 1 to 28) and Comparative Examples (Nos. 29 to 34) are shown. The numerical values in the parentheses in Tables 1 to 6 are calculated values.

Raw materials of respective components were made up so as to have a composition shown in Tables 1 to 6, and a sulfate was added to the raw materials in an amount of 0.1 parts by mass as converted into SO₃ amount based on 100 parts by mass of the raw materials of the components for the glass substrate, followed by heating and melting at a temperature of 1,600° C. for 3 hours using a platinum crucible. In melting, a platinum stirrer was inserted, and stirring was performed for one hour, thereby homogenizing the glass. Subsequently, the molten glass was flown out and formed into a sheet form, followed by cooling to obtain a glass sheet.

With respect to the thus obtained glass sheets, an average coefficient of thermal expansion (unit: ×10⁻⁷/° C.) within the range of from 50 to 350° C., a glass transition temperature Tg (unit: ° C.), a temperature (T₄) (unit: ° C.) at which the viscosity reached 10⁴ dPa·s, a temperature (T₂) (unit: ° C.) at which the viscosity reached 10² dPa·s, a devitrification temperature (T_{L}) (unit: ° C.), a density (unit: g/cm³), a brittleness index (unit: m^{-1/2}), Young's modulus, and an average transmittance (unit: %) were measured and shown in Tables 1 to 3. Measuring methods of respective physical properties are shown below.

In Examples, respective physical properties are measured for the glass sheet, but are the same values in the glass sheet and the glass substrate. The glass substrate can be formed by subjecting the obtained glass sheet to processing and polishing.

(1) Tg: Tg is a value as measured using a differential thermal expansion meter (TMA) in conformity with JIS R3103-3 (2001).

(2) Average coefficient of thermal expansion within the range of from 50 to 350° C.: The average coefficient of thermal expansion was measured using TMA and determined in conformity with JIS R3102 (1995).

(3) Viscosity: The viscosity was measured using a rotary viscometer. A temperature T₂ (a reference temperature for melting properties) at which the viscosity η thereof reached 10² dPa·s and a temperature T₄ (a reference temperature for formability) at which the viscosity η thereof reached 10⁴ dPa·s were measured.

(4) Devitrification temperature (T_{L}): 5 g of a glass block cut from the glass sheet were put on a platinum dish and maintained at a predetermined temperature for 17 hours in an electric furnace. A maximum value of a temperature at which a crystal was not precipitated on and inside the glass block was defined as the devitrification temperature.

(5) Density: About 20 g of a glass block containing no foam was measured by Archimedes method.

(6) Brittleness index: The brittleness index B is calculated using a size of Vickers indentation marks formed on the surface of the aforementioned various glass sheets and the formula (1).

(7) Young's modulus: The Young's modulus was measured for a glass sheet having a thickness of from 7 to 10 mm by an ultrasonic pulse method.

(8) Average transmittance Tave: A sample obtained by mirror polishing both surfaces of a glass sheet having a size of 3 cm×3 cm and a thickness of from 1 to 2 mm with cerium oxide was prepared, transmittance at a wavelength of from 300 to 2,000 nm was measured, and an average transmittance Tave (unit: %) at a wavelength of from 500 to 800 nm when a thickness of a glass substrate was converted into 2 mm was calculated by the following formula (4). T is the measured average transmittance at a wavelength from 500 to 800 nm, and t is a thickness of a sample. It is assumed that reflectivity of the sample is 8%.

Tave=92(T/92)^{2/t} (4)

Residual SO₃ amount in the glass was from 100 to 500 ppm.

TABLE 1

| Composition [mol %] | No. 1 | No. 2 | No. 3 | No. 4 | No. 5 | No. 6 |
|---|---|---|---|---|---|---|
| SiO₂ | 64.5 | 66.0 | 69.5 | 68.5 | 66.0 | 65.5 |
| Al₂O₃ | 6.5 | 5.0 | 2.0 | 3.5 | 6.0 | 6.0 |
| B₂O₃ | 0 | 0 | 0 | 0 | 0 | 0 |
| MgO | 12.0 | 11.5 | 12.0 | 12.0 | 11.0 | 11.0 |
| CaO | 2.5 | 3.5 | 3.5 | 3.5 | 3.5 | 5.0 |
| SrO | 1.0 | 1.0 | 1.5 | 0 | 0.5 | 0.62 |
| BaO | 0 | 0.5 | 1.0 | 0 | 0.5 | 0.13 |
| ZrO₂ | 2.0 | 2.0 | 2.0 | 2.0 | 1.5 | 1.75 |
| TiO₂ | 0 | 0 | 0 | 0 | 0 | 0 |
| Na₂O | 4.5 | 5.0 | 1.5 | 3.5 | 5.0 | 5.0 |
| K₂O | 7.0 | 5.5 | 7.0 | 7.0 | 6.0 | 5.0 |
| MgO + CaO + SrO + BaO | 15.50 | 16.50 | 18.00 | 15.50 | 15.50 | 16.75 |
| Na₂O + K₂O | 11.5 | 10.5 | 8.5 | 10.5 | 11.0 | 10.0 |
| MgO/Al₂O₃ | 1.85 | 2.30 | 6.00 | 3.43 | 1.83 | 1.83 |
| (2Na₂O + K₂O + SrO + BaO)/ | 2.00 | 2.43 | 3.13 | 2.55 | 2.27 | 2.03 |
| (Al₂O₃ + ZrO₂) | | | | | | |
| Na₂O/K₂O | 0.64 | 0.91 | 0.21 | 0.50 | 0.83 | 1.00 |
| MgO/(MgO + CaO + SrO + BaO) | 0.77 | 0.70 | 0.67 | 0.77 | 0.71 | 0.66 |
| −0.94MgO + 11 | −0.28 | 0.19 | −0.28 | −0.28 | 0.66 | 0.66 |
| −0.94MgO + 12 | 0.72 | 1.19 | 0.72 | 0.72 | 1.66 | 1.66 |
| −0.48MgO + 6.5 | 0.74 | 0.98 | 0.74 | 0.74 | 1.22 | 1.22 |
| −0.48MgO + 7 | 1.24 | 1.48 | 1.24 | 1.24 | 1.72 | 1.72 |
| Fe₂O₃ (wt %) | 0.05 | 0.05 | 0.05 | 0.05 | 0.05 | 0.10 |
| Density (g/cm³) | (2.54) | (2.56) | (2.57) | 2.51 | 2.54 | 2.55 |
| Average coefficient of thermal | (79) | (76) | (72) | 76 | 79 | 76 |
| expansion | | | | | | |
| (×10⁻⁷/° C.) | | | | | | |
| Tg (° C.) | (662) | (653) | (661) | 660 | 650 | 657 |
| T₄ (° C.) | (1226) | (1197) | (1208) | (1217) | (1213) | 1202 |
| T₂ (° C.) | (1648) | (1616) | (1627) | (1648) | (1641) | 1596 |
| Devitrification temperature T_{L} (° C.) | 1225 | 1175 | 1200 | 1200 | 1200 | 1215 |
| T₄ − T_{L} | 1 | 22 | 8 | 17 | 13 | −13 |
| Brittleness index (m^{-1/2}) | (5950) | (6150) | (6200) | 5850 | 6050 | 6400 |
| Young's modulus (GPa) | (76.4) | (77.6) | (76.5) | 74.9 | (76.1) | 79 |
| Specific elastic modulus | (30.1) | (30.3) | (29.8) | (29.8) | (30.0) | 31 |
| (GPa·cm³/g) | | | | | | |
| Tave (%) | (90.6) | (90.8) | (90.3) | 90.5 | 90.6 | 89.5 |
| (as converted into 2 mm thickness) | | | | | | |

*Fe₂O₃ is an amount as converted into parts by mass based on 100 parts by mass of base composition.

TABLE 2

| Composition [mol %] | No. 7 | No. 8 | No. 9 | No. 10 | No. 11 | No. 12 |
|---|---|---|---|---|---|---|
| SiO₂ | 65.75 | 66.0 | 65.25 | 65.5 | 66.25 | 66.5 |
| Al₂O₃ | 6.5 | 6.25 | 6.25 | 6.0 | 5.5 | 5.0 |
| B₂O₃ | 0 | 0 | 0 | 0 | 0 | 0 |
| MgO | 10.25 | 10.0 | 10.0 | 11.0 | 10.5 | 12.0 |
| CaO | 5.25 | 5.5 | 5.5 | 5.0 | 5.5 | 5.0 |
| SrO | 0 | 0 | 0.75 | 0.62 | 0.75 | 0 |
| BaO | 0 | 0 | 0.5 | 0.13 | 1.0 | 0 |
| ZrO₂ | 1.75 | 1.75 | 1.75 | 1.75 | 1.5 | 1.5 |
| TiO₂ | 0 | 0 | 0 | 0 | 0 | 0 |
| Na₂O | 6.25 | 6.0 | 5.0 | 5.0 | 4.0 | 4.0 |
| K₂O | 4.25 | 4.5 | 5.0 | 5.0 | 5.0 | 6.0 |
| MgO + CaO + SrO + BaO | 15.50 | 15.50 | 16.75 | 16.75 | 17.75 | 17.0 |
| Na₂O + K₂O | 10.5 | 10.5 | 10.0 | 10.0 | 9.0 | 10.0 |
| MgO/Al₂O₃ | 1.58 | 1.60 | 1.60 | 1.83 | 1.91 | 2.40 |
| (2Na₂O + K₂O + SrO + BaO)/ | 2.03 | 2.06 | 2.03 | 2.03 | 2.11 | 2.15 |
| (Al₂O₃ + ZrO₂) | | | | | | |
| Na₂O/K₂O | 1.47 | 1.33 | 1.00 | 1.00 | 0.80 | 0.67 |
| MgO/(MgO + CaO + SrO + BaO) | 0.66 | 0.65 | 0.60 | 0.66 | 0.59 | 0.71 |
| −0.94MgO + 11 | 1.37 | 1.60 | 1.60 | 0.66 | 1.13 | −0.28 |
| −0.94MgO + 12 | 2.37 | 2.60 | 2.60 | 1.66 | 2.13 | 0.72 |
| −0.48MgO + 6.5 | 1.58 | 1.70 | 1.70 | 1.22 | 1.46 | 0.74 |
| −0.48MgO + 7 | 2.08 | 2.20 | 2.20 | 1.72 | 1.96 | 1.24 |
| Fe₂O₃ (wt %) | 0.05 | 0.05 | 0.05 | 0.05 | 0.05 | 0.05 |
| Density (g/cm³) | 2.54 | 2.54 | 2.57 | 2.55 | 2.58 | 2.52 |
| Average coefficient of | 78 | 79 | 77 | 76 | 75 | 75.0 |
| thermal expansion | | | | | | |
| (×10⁻⁷/° C.) | | | | | | |
| Tg (° C.) | 652 | 650 | 653 | 657 | 655 | 655 |
| T₄ (° C.) | (1201) | (1200) | 1200 | 1202 | 1216 | (1201) |
| T₂ (° C.) | (1625) | (1623) | 1597 | 1596 | 1625 | (1622) |
| Devitrification | 1220 | 1220 | 1230 | 1215 | 1215 | 1230 |
| temperature T_{L} (° C.) | | | | | | |
| T₄ − T_{L} | −19 | −20 | −30 | −13 | 1 | −29 |
| Brittleness index (m^{-1/2}) | 5800 | 6150 | 6200 | 6400 | 6150 | 6050 |
| Young's modulus (GPa) | (78.2) | (77.9) | (78.0) | 79 | 77 | (77.5) |
| Specific elastic modulus | (30.8) | (30.7) | (30.4) | 31 | 30 | (30.8) |
| (GPa · cm³/g) | | | | | | |
| Tave (%) (as converted | 90.8 | 90.9 | 90.7 | 90.7 | 90.5 | 90.5 |
| into 2 mm thickness) | | | | | | |

*Fe₂O₃ is an amount as converted into parts by mass based on 100 parts by mass of base composition.

TABLE 3

| Composition [mol %] | No. 13 | No. 14 | No. 15 | No. 16 | No. 17 | No. 18 |
|---|---|---|---|---|---|---|
| SiO₂ | 66.5 | 64.75 | 66.5 | 65.5 | 65.5 | 65.5 |
| Al₂O₃ | 7.0 | 6.5 | 6.25 | 6.0 | 5.5 | 6.0 |
| B₂O₃ | 0 | 0 | 0 | 0 | 0 | 0 |
| MgO | 11.0 | 11.0 | 11.0 | 11.0 | 11.25 | 11.0 |
| CaO | 5.75 | 5.0 | 4.25 | 5.0 | 5.25 | 4.75 |
| SrO | 0.25 | 1.0 | 1.0 | 0.62 | 0.62 | 0.62 |
| BaO | 1.5 | 0 | 0 | 0.13 | 0.13 | 0.13 |
| ZrO₂ | 0 | 2.0 | 1.75 | 1.75 | 1.75 | 1.75 |
| TiO₂ | 0 | 0 | 0 | 0 | 0 | 0 |
| Na₂O | 4.25 | 4.5 | 4.75 | 3.0 | 3.0 | 3.25 |
| K₂O | 3.75 | 5.25 | 4.5 | 7.0 | 7.0 | 7.0 |
| MgO + CaO + SrO + BaO | 18.5 | 17.0 | 16.3 | 16.8 | 17.3 | 16.5 |
| Na₂O + K₂O | 8.0 | 9.8 | 9.3 | 10.0 | 10.0 | 10.3 |
| MgO/Al₂O₃ | 1.57 | 1.69 | 1.76 | 1.83 | 2.05 | 1.83 |
| (2Na₂O + K₂O + SrO + BaO)/ | 2.00 | 1.79 | 1.88 | 1.77 | 1.90 | 1.84 |
| (Al₂O₃ + ZrO₂) | | | | | | |
| Na₂O/K₂O | 1.13 | 0.86 | 1.06 | 0.43 | 0.43 | 0.46 |
| MgO/(MgO + CaO + SrO + BaO) | 0.59 | 0.65 | 0.68 | 0.66 | 0.65 | 0.67 |
| −0.94MgO + 11 | 0.66 | 0.66 | 0.66 | 0.66 | 0.43 | 0.66 |
| −0.94MgO + 12 | 1.66 | 1.66 | 1.66 | 1.66 | 1.43 | 1.66 |
| −0.48MgO + 6.5 | 1.22 | 1.22 | 1.22 | 1.22 | 1.10 | 1.22 |
| −0.48MgO + 7 | 1.72 | 1.72 | 1.72 | 1.72 | 1.60 | 1.72 |
| Fe₂O₃ (wt %) | 0.05 | 0.05 | 0.05 | 0.05 | 0.05 | 0.05 |
| Density (g/cm³) | (2.54) | 2.57 | 2.55 | 2.55 | (2.54) | 2.55 |
| Average coefficient of | 72 | 76 | 73 | 78 | (75) | 78 |
| thermal expansion | | | | | | |
| (×10⁻⁷/° C.) | | | | | | |
| Tg (° C.) | 659 | 668 | 668 | 674 | (679) | 670 |
| T₄ (° C.) | (1208) | 1212 | 1226 | 1227 | (1230) | (1219) |
| T₂ (° C.) | (1631) | 1615 | 1635 | 1635 | (1650) | (1636) |
| Devitrification | 1238 | 1220 | 1240 | 1226 | 1246 | <1220 |
| temperature T_{L} (° C.) | | | | | | |
| T₄ − T_{L} | −30 | −8 | −14 | 1 | −16 | >−1 |
| Brittleness index (m^{-1/2}) | (6050) | (5950) | (5850) | (5900) | (5950) | 6050 |
| Young's modulus (GPa) | (77.8) | (78.9) | (78.6) | (76.9) | (76.7) | (76.7) |
| Specific elastic modulus | (30.6) | (30.7) | (30.8) | (30.2) | (30.2) | (30.1) |
| (GPa · cm³/g) | | | | | | |
| Tave (%) (as converted | 90.5 | (90.6) | 90.5 | 90.3 | (90.4) | 90.5 |
| into 2 mm thickness) | | | | | | |

*Fe₂O₃ is an amount as converted into parts by mass based on 100 parts by mass of base composition.

TABLE 4

| Composition [mol %] | No. 19 | No. 20 | No. 21 | No. 22 | No. 23 |
|---|---|---|---|---|---|
| SiO₂ | 65.0 | 66.5 | 69.0 | 68.5 | 65.0 |
| Al₂O₃ | 6.35 | 4.75 | 3.25 | 3.5 | 6.0 |
| B₂O₃ | 0 | 0 | 0 | 0 | 0 |
| MgO | 11.0 | 11.75 | 11.0 | 12.0 | 11.0 |
| CaO | 4.8 | 4.5 | 4.0 | 3.5 | 2.0 |
| SrO | 0.75 | 0 | 2.0 | 0.5 | 2.0 |
| BaO | 0.1 | 0 | 0 | 0 | 1.25 |
| ZrO₂ | 2.0 | 1.75 | 1.5 | 2.0 | 1.75 |
| TiO₂ | 0 | 0 | 0 | 0 | 0 |
| Na₂O | 4.5 | 4.0 | 2.75 | 4.0 | 3.75 |
| K₂O | 5.5 | 6.75 | 6.5 | 6.0 | 7.25 |
| MgO + CaO + SrO + BaO | 16.7 | 16.3 | 17.0 | 16.0 | 16.3 |
| Na₂O + K₂O | 10.0 | 10.8 | 9.3 | 10.0 | 11.0 |
| MgO/Al₂O₃ | 1.73 | 2.47 | 3.38 | 3.43 | 1.83 |
| (2Na₂O + K₂O + SrO + BaO)/(Al₂O₃ + ZrO₂) | 1.84 | 2.27 | 2.95 | 2.64 | 2.32 |
| Na₂O/K₂O | 0.82 | 0.59 | 0.42 | 0.67 | 0.52 |
| MgO/(MgO + CaO + SrO + BaO) | 0.66 | 0.72 | 0.65 | 0.75 | 0.68 |
| −0.94MgO + 11 | 0.66 | −0.04 | 0.66 | −0.28 | 0.66 |
| −0.94MgO + 12 | 1.66 | 0.96 | 1.66 | 0.72 | 1.66 |
| −0.48MgO + 6.5 | 1.22 | 0.86 | 1.22 | 0.74 | 1.22 |
| −0.48MgO + 7 | 1.72 | 1.36 | 1.72 | 1.24 | 1.72 |
| Fe₂O₃ (wt %) | 0.05 | 0.05 | 0.05 | 0.05 | 0.05 |
| Density (g/cm³) | 2.57 | (2.52) | 2.54 | (2.52) | (2.59) |
| Average coefficient of thermal expansion | 77 | (77) | 73 | (74) | (78) |
| (×10⁻⁷/° C.) | | | | | |
| Tg (° C.) | 665 | (660) | 655 | (652) | (655) |
| T₄ (° C.) | 1206 | (1202) | (1212) | (1211) | (1220) |
| T₂ (° C.) | 1606 | (1624) | (1646) | (1641) | (1639) |
| Devitrification temperature T_{L} (° C.) | 1220 | 1215 | <1230 | <1230 | <1236 |
| T₄ − T_{L} | −14 | −13 | >−18 | >−19 | >−16 |
| Brittleness index (m^{-1/2}) | (5950) | (6000) | 5850 | 6200 | 6200 |
| Young's modulus (GPa) | (78.4) | (76.5) | (76.4) | (76.9) | (75.4) |
| Specific elastic modulus (GPa · cm³/g) | (30.5) | (30.4) | (30.1) | (30.5) | (29.1) |
| Tave (%) | 90.5 | (90.6) | 90.4 | (90.6) | 90.2 |
| (as converted into 2 mm thickness) | | | | | |

*Fe₂O₃ is an amount as converted into parts by mass based on 100 parts by mass of base composition.

TABLE 5

| Composition [mol %] | No. 24 | No. 25 | No. 26 | No. 27 | No. 28 |
|---|---|---|---|---|---|
| SiO₂ | 65.5 | 65.75 | 65.5 | 66.25 | 66.0 |
| Al₂O₃ | 5.75 | 5.5 | 6.0 | 5.5 | 6.0 |
| B₂O₃ | 0 | 0 | 0.5 | 0.5 | 0 |
| MgO | 11.0 | 10.0 | 10.75 | 10.5 | 10.0 |
| CaO | 4.0 | 4.5 | 5.0 | 5.5 | 3.5 |
| SrO | 0.5 | 0.5 | 0.5 | 0.75 | 0 |
| BaO | 0 | 0 | 0 | 0.5 | 0 |
| ZrO₂ | 1.75 | 1.75 | 1.75 | 1.5 | 1.5 |
| TiO₂ | 0 | 0 | 0 | 0 | 2.0 |
| Na₂O | 3.0 | 3.5 | 5.0 | 4.0 | 5.0 |
| K₂O | 8.5 | 8.5 | 5.0 | 5.0 | 6.0 |
| MgO + CaO + SrO + BaO | 15.5 | 15.0 | 16.3 | 17.3 | 13.5 |
| Na₂O + K₂O | 11.5 | 12.0 | 10.0 | 9.0 | 11.0 |
| MgO/Al₂O₃ | 1.91 | 1.82 | 1.79 | 1.91 | 1.67 |
| (2Na₂O + K₂O + SrO + BaO)/(Al₂O₃ + ZrO₂) | 2.00 | 2.21 | 2.00 | 2.04 | 2.13 |
| Na₂O/K₂O | 0.35 | 0.41 | 1.00 | 0.80 | 0.83 |
| MgO/(MgO + CaO + SrO + BaO) | 0.71 | 0.67 | 0.66 | 0.61 | 0.74 |
| −0.94MgO + 11 | 0.66 | 1.60 | 0.90 | 1.13 | 1.60 |
| −0.94MgO + 12 | 1.66 | 2.60 | 1.90 | 2.13 | 2.60 |
| −0.48MgO + 6.5 | 1.22 | 1.70 | 1.34 | 1.46 | 1.70 |
| −0.48MgO + 7 | 1.72 | 2.20 | 1.84 | 1.96 | 2.20 |
| Fe₂O₃ (wt %) | 0.05 | 0.05 | 0.05 | 0.05 | 0.05 |
| Density (g/cm³) | 2.58 | 2.54 | 2.55 | 2.56 | 2.52 |
| Average coefficient of thermal expansion | (80) | 83 | 77 | 75 | 77 |
| (×10⁻⁷/° C.) | | | | | |
| Tg (° C.) | (665) | 651 | 652 | 652 | 651 |
| T₄ (° C.) | (1223) | (1212) | (1203) | (1211) | 1213 |
| T₂ (° C.) | (1646) | (1637) | (1605) | (1614) | 1626 |
| Devitrification temperature T_{L} (° C.) | <1240 | <1227 | <1223 | <1231 | 1200 |
| T₄ − T_{L} | >−17 | >−15 | >−20 | >−20 | 13 |
| Brittleness index (m^{-1/2}) | (5950) | 6200 | 6250 | 6200 | 5900 |
| Young's modulus (GPa) | (74.8) | (74.2) | (79.0) | (78.9) | (77.5) |
| Specific elastic modulus (GPa · cm³/g) | (29.0) | (29.2) | (31.0) | (30.8) | (30.8) |
| Tave (%) | (90.2) | 90.2 | 90.4 | 90.2 | 90.4 |
| (as converted into 2 mm thickness) | | | | | |

*Fe₂O₃ is an amount as converted into parts by mass based on 100 parts by mass of base composition.

TABLE 6

| Composition [mol %] | No. 29 | No. 30 | No. 31 | No. 32 | No. 33 | No. 34 |
|---|---|---|---|---|---|---|
| SiO₂ | 61.0 | 63.0 | 64.5 | 66.5 | 67.0 | 67.0 |
| Al₂O₃ | 9.0 | 9.5 | 5.5 | 4.7 | 4.9 | 4.9 |
| B₂O₃ | 0 | 0 | 0 | 0 | 0 | 0 |
| MgO | 15.5 | 9.5 | 11.5 | 3.4 | 3.4 | 3.4 |
| CaO | 2.5 | 2.5 | 7.0 | 6.2 | 2.6 | 2.6 |
| SrO | 1.0 | 0 | 0.5 | 4.7 | 5.9 | 5.9 |
| BaO | 0 | 0 | 1.0 | 3.6 | 3.9 | 3.9 |
| ZrO₂ | 0 | 2.0 | 1.5 | 1.7 | 2.6 | 2.6 |
| TiO₂ | 0 | 0 | 0 | 0 | 0 | 0 |
| Na₂O | 4.5 | 6.5 | 2.0 | 4.8 | 4.9 | 4.9 |
| K₂O | 6.5 | 7.0 | 6.5 | 4.4 | 4.8 | 4.8 |
| MgO + CaO + SrO + BaO | 19.0 | 12.0 | 20.0 | 17.9 | 15.8 | 15.8 |
| Na₂O + K₂O | 11.0 | 13.5 | 8.5 | 9.2 | 9.7 | 9.7 |
| MgO/Al₂O₃ | 1.72 | 1.00 | 2.09 | 0.72 | 0.69 | 0.69 |
| (2Na₂O + K₂O + SrO + BaO)/ | 1.83 | 1.74 | 1.71 | 3.48 | 3.25 | 3.25 |
| (Al₂O₃ + ZrO₂) | | | | | | |
| Na₂O/K₂O | 0.69 | 0.93 | 0.31 | 1.09 | 1.02 | 1.02 |
| MgO/(MgO + CaO + SrO + BaO) | 0.82 | 0.79 | 0.58 | 0.19 | 0.22 | 0.22 |
| −0.94MgO + 11 | −3.57 | 2.07 | 0.19 | 7.80 | 7.80 | 7.80 |
| −0.94MgO + 12 | −2.57 | 3.07 | 1.19 | 8.80 | 8.80 | 8.80 |
| −0.48MgO + 6.5 | −0.94 | 1.94 | 0.98 | 4.87 | 4.87 | 4.87 |
| −0.48MgO + 7 | −0.44 | 2.44 | 1.48 | 5.37 | 5.37 | 5.37 |
| Fe₂O₃ (wt %) | 0.05 | 0.05 | 0.05 | 0.05 | 0.05 | 0.10 |
| Density (g/cm³) | 2.52 | 2.53 | 2.59 | 2.77 | 2.81 | 2.81 |
| Average coefficient of | 82 | 86 | (75) | 83 | 76 | 76 |
| thermal expansion | | | | | | |
| (×10⁻⁷/° C.) | | | | | | |
| Tg (° C.) | 664 | 667 | (670) | 620 | 630 | 630 |
| T₄ (° C.) | (1213) | (1252) | (1182) | 1136 | 1194 | 1194 |
| T₂ (° C.) | (1633) | (1685) | (1573) | 1537 | 1602 | 1602 |
| Devitrification | >1263 | >1302 | >1230 | 1080 | | |
| temperature T_{L} (° C.) | | | | | | |
| T₄ − T_{L} | <−50 | <−50 | <−48 | 56 | | |
| Brittleness index (m^{-1/2}) | 5900 | 5700 | (6100) | 7000 | | |
| Young's modulus (GPa) | (78.2) | (74.6) | (78.6) | 76 | | |
| Specific elastic modulus | (31.0) | (29.5) | (30.3) | 27.0 | | |
| (GPa · cm³/g) | | | | | | |
| Tave (%) (as converted | 91.1 | (90.4) | (90.4) | (90.0) | 90.1 | 88.2 |
| into 2 mm thickness) | | | | | | |

*Fe₂O₃ is an amount as converted into parts by mass based on 100 parts by mass of base composition.

As is clear from Tables 1 to 6, the glass substrates of Examples (Nos. 1 to 28) have the characteristics of a glass substrate for a solar cell with good balance such that T₄-T_{L} is −30° C. or higher, the glass transition temperature Tg is as high as 640° C. or higher, the average coefficient of thermal expansion within the range of from 50 to 350° C. is from 70×10⁻⁷ to 90×10⁻⁷/° C., and the density is 2.7 g/cm³ or less. Therefore, the CdTe layer is not peeled from the glass substrate, and the glass substrate is less prone to deform during assembling the solar cell (specifically, during laminating the glass substrate and the back sheet glass under heating such that the photoelectric conversion layer such as the CdTe layer is sandwiched between those).

Moreover, high glass transition temperature, a predetermined average coefficient of thermal expansion, high glass strength, low glass density, and prevention of devitrification during the sheet glass production can be all achieved. Moreover, since T₂ is 1,650° C. or lower and T₄ is 1,230° C. or lower, meltability and formability during the sheet glass production are excellent.

Additionally, in the glass substrates of Examples (Nos. 1 to 28), since the value of the formula (2) is 0.4 or more, the transmittance tends to be high as compared with that of Comparative Examples (Nos. 32 to 34), and low density suitable for use in a CdTe solar cell is realized.

On the other hand, as shown in Table 6, in the glass substrates of Comparative Examples (Nos. 29 to 31), since T₄-T_{L} is lower than −30° C. and the glass substrate are prone to be denitrified, it is difficult to conduct forming by a float process. Moreover, Tg is low in Comparative Examples (Nos. 32 to 34), and thus, the glass substrate is prone to deform during film formation at 600° C. or higher.

The glass substrate for a CdTe solar cell of the embodiment of the present invention is suitable as a glass substrate and cover glass for a CdTe solar cell, and also can be used as a substrate and cover glass for other solar cells.

The glass substrate for a CdTe solar cell of the embodiments of the present invention can have properties of high transmittance, high glass transition temperature, a predetermined average coefficient of thermal expansion, high glass strength, low glass density, and meltability, formability and prevention of devitrification upon sheet glass forming with good balance, and a solar cell exhibiting high cell efficiency can be provided by using the glass substrate for a CdTe solar cell of the embodiment of the present invention.

The glass substrate of the embodiments of the present invention can suitably used for a glass substrate for a CdTe solar cell, the CdTe solar cell including a glass substrate and a back sheet glass, in which a photoelectric conversion layer including, as a main component, Group 12-16 compound semiconductors of a cubic system or a hexagonal system is formed between the glass substrate and the back sheet glass.

The present invention is not construed as being limited to the above-mentioned embodiments in any way, and can be carried out in various modes within a scope not departing from the gist thereof.

1. A glass substrate for a CdTe solar cell, comprising, in terms of mol % on a basis of following oxides:
from 60 to 75% of SiO₂;
from 1 to 7.5% of Al₂O₃;
from 0 to 1% of B₂O₃;
from 8.5 to 12.5% of MgO;
from 1 to 6.5% of CaO;
from 0 to 3% of SrO;
from 0 to 3% of BaO;
from 0 to 3% of ZrO₂;
from 1 to 8% of Na₂O; and
from 2 to 12% of K₂O,
wherein MgO+CaO+SrO+BaO is from 10 to 24%,
Na₂O+K₂O is from 5 to 15%,
MgO/Al₂O₃ is 1.3 or more,
(2Na₂O+K₂O+SrO+BaO)/(Al₂O₃+ZrO₂) is 3.3 or less,
Na₂O/K₂O is from 0.2 to 2.0,
Al₂O₃≧−0.94MgO+11, and
CaO≧−0.48MgO+6.5,
wherein the glass substrate has a glass transition temperature of 640° C. or higher, an average coefficient of thermal expansion within a range of from 50 to 350° C. of from 70×10⁻⁷ to 90×10⁻⁷/° C., a temperature (T₄), at which a viscosity reaches 10⁴ dPa·s, of 1,230° C. or lower, a temperature (T₂), at which a viscosity reaches 10² dPa·s, of 1,650° C. or lower, a relationship between the T₄ and a devitrification temperature (T_{L}) of T₄-T_{L}≧−30° C., and a density of 2.7 g/cm³ or less.

2. The glass substrate for a CdTe solar cell according to claim 1, comprising, in terms of mol % on the basis of the following oxides:
from 62 to 73% of SiO₂;
from 1.5 to 7% of Al₂O₃;
from 0 to 1% of B₂O₃;
from 9 to 12.5% of MgO;
from 1.5 to 6.5% of CaO;
from 0 to 2.5% of SrO;
from 0 to 2% of BaO;
from 0.5 to 3% of ZrO₂;
from 1 to 7.5% of Na₂O, and
from 2 to 10% of K₂O,
wherein MgO+CaO+SrO+BaO is from 11 to 22%,
Na₂O+K₂O is from 6 to 13%,
MgO/Al₂O₃ is 1.4 or more,
(2Na₂O+K₂O+SrO+BaO)/(Al₂O₃+ZrO₂) is from 0.5 to 3,
Na₂O/K₂O is from 0.4 to 1.5,
Al₂O₃≧−0.94MgO+12, and
CaO≧−0.48MgO+7,
wherein the glass substrate has the glass transition temperature of 645° C. or higher, the average coefficient of thermal expansion within a range of from 50 to 350° C. of from 70×10⁻⁷ to 85×10⁻⁷/° C., the temperature (T₄) of 1,220° C. or lower, the temperature (T₂) of 1,630° C. or lower, the relationship between the T₄ and the devitrification temperature (T_{L}) of T₄-T_{L}≧−20° C., and the density of 2.6 g/cm³ or less.

3. The glass substrate for a CdTe solar cell according to claim 1, wherein a total iron amount, measured as Fe₂O₃, is 0.06 parts by mass or less based on 100 parts by mass of a total amount of SiO₂, Al₂O₃, MgO, CaO, SrO, BaO, ZrO₂, Na₂O and K₂O.

4. The glass substrate for a CdTe solar cell according to claim 1, wherein MgO/(MgO+CaO+SrO+BaO) is 0.4 or more in terms of mol % on the basis of the oxides.

5. The glass substrate for a CdTe solar cell according to claim 1, further comprising from 0 to 3% of TiO₂.

6. The glass substrate for a CdTe solar cell according to claim 2, further comprising from 0 to 3% of TiO₂.

7. A solar cell comprising:
the glass substrate according to claim 1;
a back sheet glass facing the glass substrate; and
a photoelectric conversion layer of CdTe provided between the glass substrate and the back sheet glass.
